(19) United States
(12) Patent Application Publication
(10) Pub. No.: US 2019/0198301 A1
(43) Pub. Date: Jun. 27, 2019

(54) Plasma Processing Apparatus and Methods

(71) Applicant: Mattson Technology, Inc., Fremont, CA (US)

(72) Inventors: Shawming Ma, Sunnyvale, CA (US); Hua Chung, Saratoga, CA (US); Michael X. Yang, Palo Alto, CA (US); Dixit V. Desai, Pleasanton, CA (US); Ryan M. Pakulski, Brentwood, CA (US)

(21) Appl. No.: 16/218,931

(22) Filed: Dec. 13, 2018

Related U.S. Application Data
(60) Provisional application No. 62/610,573, filed on Dec. 27, 2017.

(51) Int. Cl. H01J 37/32; H01L 21/3065; H01L 21/687

(52) U.S. Cl. CPC H01J 37/32899; H01L 21/3065; H01L 21/68742; H01J 37/32357; H01J 37/32119; H01J 2237/3342; H01J 37/32568; H01J 37/32715; H01J 37/32458; H01J 2237/3345; H01J 2237/3341; H01J 37/32449

(57) ABSTRACT

Plasma processing apparatus and methods are provided. In one example implementation, the plasma processing apparatus includes a processing chamber. The plasma processing apparatus includes a pedestal disposed in the processing chamber. The pedestal is operable to support a workpiece. The plasma processing apparatus includes a plasma chamber disposed above the processing chamber in a vertical direction. The plasma chamber includes a dielectric sidewall. The plasma processing apparatus includes a separation grid separating the processing chamber from the plasma chamber. The plasma processing apparatus includes a first plasma source proximate the dielectric sidewall. The first plasma source is operable to generate a remote plasma in the plasma chamber above the separation grid. The plasma processing apparatus includes a second plasma source. The second plasma source is operable to generate a direct plasma in the processing chamber below the separation grid.

### PRIORITY CLAIM

The present application claims the benefit of priority of U.S. Provisional Patent Application Ser. No. 62/610,573, filed Dec. 27, 2017, titled “Plasma Processing Apparatus and Methods,” which is incorporated herein by reference for all purposes.

### FIELD

The present disclosure relates generally to apparatus, systems, and methods for processing a workpiece using a plasma source.

### BACKGROUND

Plasma processing is widely used in the semiconductor industry for deposition, etching, resist removal, and related processing of semiconductor wafers and other substrates. Plasma sources (e.g., microwave, ECR, inductive, etc.) are often used for plasma processing to produce high density plasma and reactive species for processing substrates.

Plasma strip tools can be used for strip processes, such as photoresist removal. Plasma strip tools can include one or more plasma chambers where plasma is generated and one or more separate processing chambers where the one or more workpieces are processed. The one or more processing chambers can be “downstream” of the one or more plasma chambers such that there is no direct exposure of the workpiece(s) to the plasma. Separation grid(s) can be used to separate the one or more processing chambers from the one or more plasma chambers. The separation grids can be transparent to neutral species but not transparent to charged species from the plasma. The one or more separation grids can include a sheet of material with holes.

Plasma etch tools can expose a workpiece directly to a plasma. The plasma can contain species such as ions, free radicals, and excited atoms and molecules that may be used to process the workpiece, such as for performing a reactive ion etching (RIE) process on the workpiece. During an RIE process, ions and other species in a plasma can be used, for instance, to remove materials deposited on a workpiece.

### SUMMARY

Aspects and advantages of embodiments of the present disclosure will be set forth in part in the following description, or may be learned from the description, or may be learned through practice of the embodiments.

One example aspect of the present disclosure is directed to a plasma processing apparatus. The plasma processing apparatus includes a processing chamber. The plasma processing apparatus includes a pedestal disposed in the processing chamber. The pedestal is operable to hold a workpiece. The plasma processing apparatus includes a plasma chamber disposed above the processing chamber in a vertical direction. The plasma chamber includes a dielectric sidewall. The plasma processing apparatus includes a separation grid separating the processing chamber from the plasma chamber. The plasma processing apparatus includes a first plasma source proximate the dielectric sidewall. The first plasma source is operable to generate a remote plasma in the plasma chamber above the separation grid. The plasma processing apparatus includes a second plasma source. The second plasma source is operable to generate a direct plasma in the processing chamber below the separation grid.

Other examples aspects of the present disclosure are directed to apparatus, methods, processes, and devices for plasma processing of a workpiece.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussion of embodiments directed to one of ordinary skill in the art are set forth in the specification, which makes reference to the appended figures, in which:

FIG. 1 depicts a plasma processing apparatus according to example embodiments of the present disclosure;

FIGS. 2A and 2B depict example vertical positioning of a workpiece in a plasma processing apparatus according to example embodiments of the present disclosure;

FIGS. 3A, 3B and 3C depict example vertical positioning of a workpiece in a plasma processing apparatus according to example embodiments of the present disclosure;

FIG. 4 depicts a plasma processing apparatus according to example embodiments of the present disclosure;

FIG. 5 depicts a plasma processing apparatus according to example embodiments of the present disclosure;

FIG. 6 depicts a plasma processing apparatus according to example embodiments of the present disclosure;

FIG. 7 depicts post plasma gas injection (PPGI) according to example embodiments of the present disclosure;

FIGS. 8 and 9 depicts tables showing parameters associated with example surface treatment processes according to example embodiments of the present disclosure.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations can be made to the embodiments without departing from the scope or spirit of the present disclosure. For instance, features illustrated or described as part of one embodiment can be used with another embodiment to yield a still further embodiment. Thus, it is intended that aspects of the present disclosure cover such modifications and variations.

Example aspects of the present disclosure are directed to plasma processing apparatus for conducting plasma processes (e.g., dry strip and/or dry etch) and other processes on workpieces, such as semiconductor wafers. According to example aspects of the present disclosure, the plasma processing apparatus can provide for plasma processes using a remotely generated plasma and/or direct exposure to plasma. In this way, the plasma processing apparatus can be used for both neutral radical based surface treatment processes (e.g., strip processes) and ion based surface treatment process (e.g., reactive ion etching processes) in a single processing apparatus.

For instance, in some embodiments, a plasma processing apparatus can include a processing chamber having a pedestal operable to support a workpiece for plasma processing. The apparatus can include a plasma chamber disposed in a vertical position above the processing chamber. A separation grid can separate the plasma chamber from the processing chamber. The apparatus can include a first plasma source configured to generate a remote plasma in the plasma chamber. The separation grid can filter ions generated in the remote plasma and allow the passage of neutral species (e.g., neutral radicals) to the processing chamber for conducting a plasma process. As used herein, a “remote plasma” refers to a plasma generated remotely from a workpiece, such as in a plasma chamber separated from a workpiece by a separation grid.

In addition, the plasma processing apparatus can include a second plasma source operable to generate a direct plasma in the processing chamber below the separation grid for direct exposure to the workpiece. Ions, neutrals, species, and other species generated in the direct plasma can be used to perform a plasma process on the workpiece. As used herein a “direct plasma” refers to a plasma that is directly exposed to a workpiece, such as a plasma generated in a processing chamber having a pedestal operable to support the workpiece.

In some embodiments, the plasma chamber can include a cylindrical dielectric sidewall. The first plasma source can include an induction coil disposed about the cylindrical dielectric sidewall. The induction coil can be energized with RF energy from an RF generator to induce a remote plasma in the plasma chamber.

When the first plasma source is not energized with RF energy, the plasma chamber and separation grid can serve as a showerhead for feeding a process gas to the processing chamber. A direct plasma can be generated in the process gas using the second plasma source. When the first plasma source is energized with RF energy to generate a remote plasma, the second plasma source can be used to re-dissociate neutrals radicals passing through the separation grid to generate the direct plasma.

In some embodiments, the plasma processing apparatus can include a dielectric window forming a part of the processing chamber (e.g., at least a portion of ceiling of the processing chamber). The dielectric window can flare in a horizontal direction (e.g., flare outward) below the plasma chamber. The second plasma source can include an induction coil located proximate the second dielectric window. The induction coil can be energized with RF energy from an RF generator to induce a direct plasma below the separation grid in the processing chamber.

In some embodiments, the second plasma source can include an RF bias source coupled to a bias electrode in the pedestal. The bias electrode can be energized with RF energy from the RF bias source to generate a direct plasma in a process gas and/or neutral radicals present in the processing chamber.

In some embodiments, the plasma processing apparatus can include a first plasma source operable to generate a remote plasma above a separation grid in the plasma chamber. The first plasma source can include an induction coil located proximate the plasma chamber. The plasma processing apparatus can include a second plasma source operable to induce a direct plasma beneath the separation grid in the processing chamber. The second plasma source can include a second induction coil located proximate a dielectric window forming a part of the processing chamber. The plasma processing apparatus can further include an RF bias source coupled to bias electrode in a pedestal for supporting a workpiece in the processing chamber. In some embodiments, the bias electrode can be energized with RF energy from the bias source to generate a direct plasma in the processing chamber.

In some embodiments, the plasma processing apparatus can be configured to provide for vertical movement of the workpiece relative to the plasma chamber/separation grid. For instance, the plasma processing apparatus can include a pedestal that is movable in a vertical direction and/or one or more lift pins movable in a vertical direction. The workpiece can be placed in a first vertical position (e.g., close to the separation grid) for a first plasma process using the remote plasma (e.g., dry strip). The workpiece can be placed in a second vertical position (e.g., away from the separation grid) for a second plasma process using the direct plasma (e.g., dry etch).

Aspects of the present disclosure are discussed with reference to a “workpiece” or “wafer” for purposes of illustration and discussion. Those of ordinary skill in the art, using the disclosures provided herein, will understand that the example aspects of the present disclosure can be used in association with any semiconductor substrate or other suitable substrate. In addition, the use of the term “about” in conjunction with a numerical value is intended to refer to within 10% of the stated numerical value.

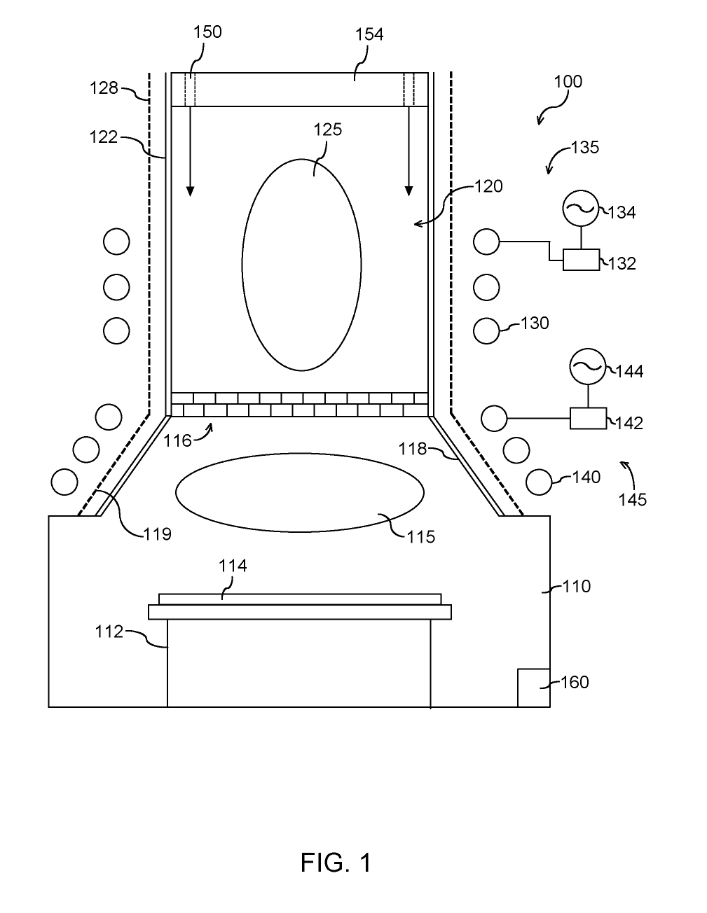

With reference now to the FIGS., example embodiments of the present disclosure will now be set forth. FIG. 1 depicts an example plasma processing apparatus 100 according to example embodiments of the present disclosure. The plasma processing apparatus 100 can include a processing chamber 110 and a plasma chamber 120 that is separate from the processing chamber 110. The plasma chamber 120 can be disposed in a vertical position above the processing chamber 110.

The processing chamber 110 can include a pedestal or substrate holder 112 operable to support a workpiece 114. The pedestal 112 can include one or more heaters, electrostatic chucks, bias electrodes, etc. In some embodiments, the pedestal 112 can be movable in a vertical direction as will be discussed in more detail below.

The apparatus 100 can include a first plasma source 135 that is operable to generate a remote plasma 125 in a process gas provided in the plasma chamber 120. Desired species (e.g. neutral species) can then be channeled from the plasma chamber 120 to the surface of workpiece 114 through holes provided in a separation grid 116 that separates the plasma chamber 120 from the processing chamber 110 (i.e., downstream region).

The plasma chamber 120 includes a dielectric side wall 122. The plasma chamber 120 includes a top plate 154. The dielectric side wall 122 and top plate 154 define a plasma chamber interior. Dielectric side wall 122 can be formed from any dielectric material, such as quartz.

The first plasma source 135 can include an induction coil 130 disposed adjacent the dielectric side wall 122 about the plasma chamber 120. The induction coil 130 can be coupled to an RF power generator 134 through a suitable matching network 132. Reactant and carrier gases can be provided to the chamber interior from gas supply 150. When the induction coil 130 is energized with RF power from the RF power generator 134, a remote plasma can be induced in the plasma chamber 120. The plasma processing apparatus 100 can include a grounded Faraday shield 128 to reduce capacitive coupling of the induction coil 130 to the remote plasma 125.

A separation grid 116 separates the plasma chamber 120 from the processing chamber 110. The separation grid 116 can be used to perform ion filtering of species generated by remote plasma 125 in the plasma chamber 120. Species passing through the separation grid 116 can be exposed to the workpiece 114 (e.g. a semiconductor wafer) in the processing chamber 110 for plasma processing of the workpiece 114 (e.g., photoresist removal).

More particularly, in some embodiments, the separation grid 116 can be transparent to neutral species but not transparent to charged species from the plasma. For example, charged species or ions can recombine on walls of the separation grid 116. The separation grid 116 can include one or more grid plates of material with holes distributed according to a hole pattern for each sheet of material. The hole patterns can be the same or different for each grid plate.

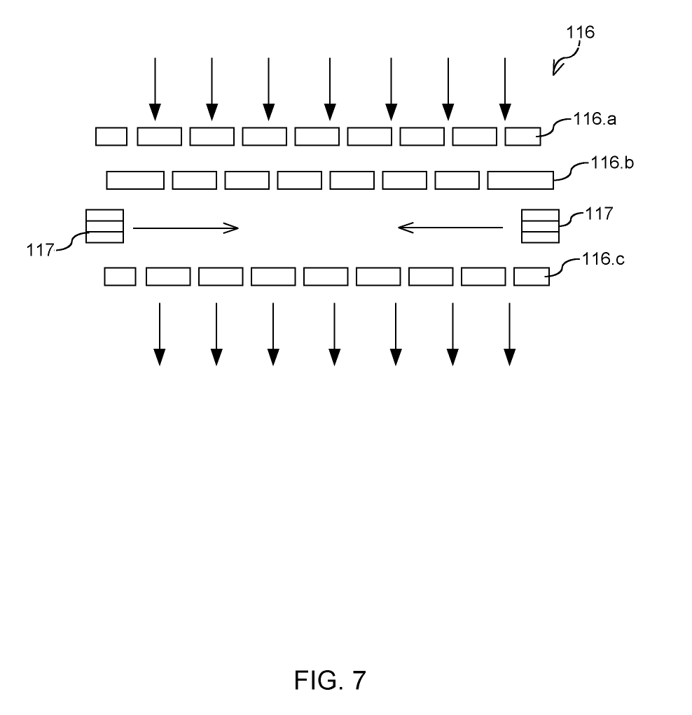

For example, the holes can be distributed according to a plurality of hole patterns on a plurality of grid plates arranged in a substantially parallel configuration such that no hole allows for a direct line of sight between the plasma chamber 120 and the processing chamber 110 to, for example, reduce or block UV light. Depending on the process, some or all of the grid can be made of a conductive material (e.g., Al, Si, SiC, etc.) and/or non-conductive material (e.g., quartz, etc.). In some embodiments, if a portion of the grid (e.g. a grid plate) is made of a conductive material, the portion of the grid can be grounded. In some embodiments, the separation grid 116 can be configured for post plasma gas injection, as discussed with reference to FIG. 7.

Referring to FIG. 1, the processing chamber 110 can include a dielectric window 118. The dielectric window 118 can flare outward and together with the separation grid 116 form at least a portion of a ceiling of the processing chamber 110. Separation grid 116 may be positioned at a junction between dielectric side wall 122 of plasma chamber 120 and dielectric window 118 of processing chamber 110, and the dielectric window 118 can flare outwardly as the dielectric window 118 extends downwardly from separation grid 116. Due to the flaring of dielectric window 118, a width of the processing chamber 110 along a horizontal direction may be greater than a width of the plasma chamber 120 along the horizontal direction. The dielectric window 118 can be made from any suitable dielectric material, such as quartz. Dielectric window 118 of processing chamber 110 may be separate from or integrally formed with dielectric side wall 122 of plasma chamber 120.

The plasma processing apparatus 100 includes a second plasma source 145. The second plasma source 145 can be operable to generate a direct plasma 115 in the processing chamber 110. For instance, when the first plasma source 135 is not used to generate a remote plasma 125, the plasma chamber 120 and/or separation grid can act as a showerhead to provide process gas to the processing chamber 110. The second plasma source 145 can be used to generate a direct plasma 115 in the process gas. Ions, neutrals, radicals, and other species generated in the direct plasma 115 can be used to for plasma processing of the workpiece 114. When the first plasma source 135 is used to generate a remote plasma 125, the second plasma source can be used to generate a direct plasma 115 by re-dissociating radicals passing through the separation grid 116.

The second plasma source 145 can include an induction coil 140 disposed adjacent the dielectric window 118. The induction coil 140 can be coupled to an RF power generator 144 through a suitable matching network 142. The RF generator 144 can be independent from RF generator 134 to provide for independent control of source power (e.g., RF power) for the first plasma source 135 and the second plasma source 145. However, in some embodiments, the RF generator 144 can be the same as RF generator 134 for the first plasma source 135. The plasma processing apparatus 100 can include a grounded Faraday shield 119 to reduce capacitive coupling of the induction coil 140 to the direct plasma 115. In some embodiments, the Faraday shield 119 can mechanically support induction coil 140.

The induction coil 140 of the second plasma source 145 can also assist with controlling uniformity within the processing chamber 110. For instance, the induction coils 130, 140 can be independently operable to control the plasma density distribution adjacent induction coils 130, 140. In particular, RF power generator 134 may be operable to independently adjust the frequency, average peak voltage or both of the RF power to the induction coil 130 of the first plasma source 135, and RF power generator 144 may be operable to independently adjust the frequency, average peak voltage or both of the RF power to the induction coil 140 of the second plasma source 145. Thus, the plasma processing apparatus 100 may have improved source tunability.

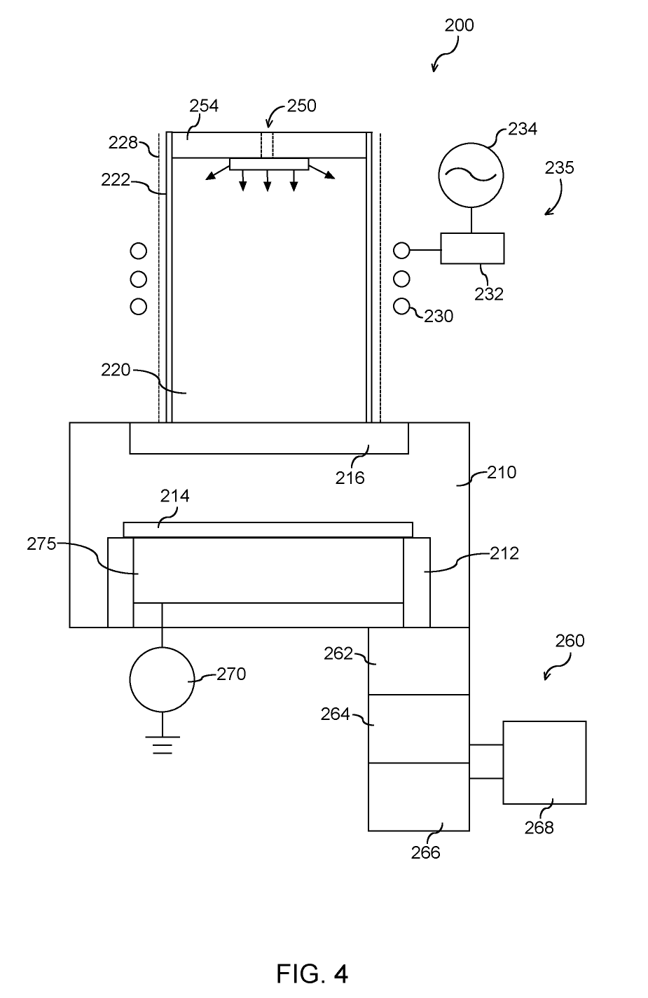

The plasma processing apparatus 100 can further include one or more pump systems 160 configured to control pressure within the processing chamber 110 and/or evacuate gasses from the processing chamber 110. Details concerning example pump systems will be discussed in greater detail below in the context of FIG. 4.

In certain example embodiments, plasma processing apparatus 100 includes features for vertical tunability of process uniformity. More particularly, a distance between a workpiece in a processing chamber and a separation grid is adjustable. For instance, in some example embodiments, a positioned of a substrate holder is adjustable along a vertical direction to adjust the distance between the workpiece on the substrate holder and the separation grid. In other example embodiments, one or more lift pins can be used to lift the workpiece and adjust the distance between the workpiece and the separation grid.

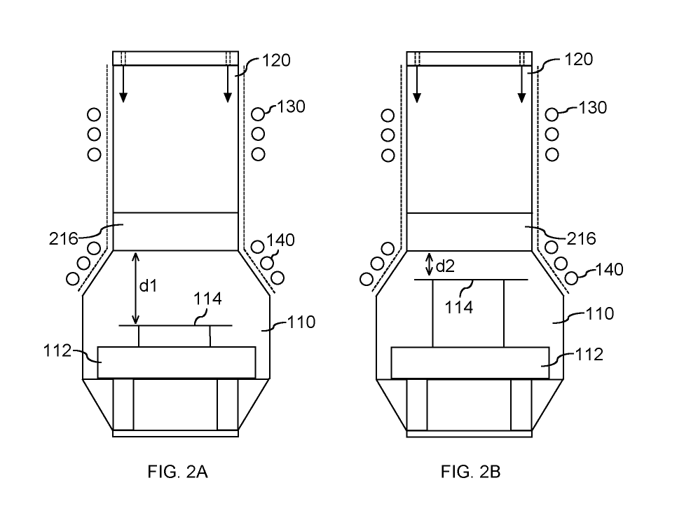

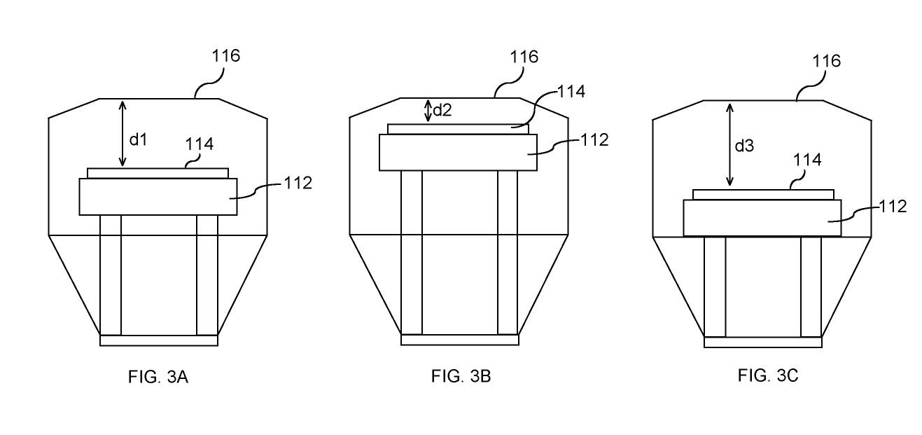

Performance of plasma processing apparatus 100 can be improved relative to known plasma processing tools by adjusting the distance between the workpiece and the separation grid. For instance, the distance between the workpiece and the separation grid can be adjusted to provide a suitable distance for a process, such as a photoresist strip process and/or a plasma etch process. As another example, the distance between distance between the workpiece and the separation grid can be adjusted to provide adjustable and/or dynamic cooling of the workpiece. In certain example, embodiments, the workpiece may remain within the plasma processing apparatus 100 between different plasma processing operations, and the distance between distance between the workpiece and the separation grid can be adjusted between the various plasma processing operations to provide a suitable distance for the current plasma processing operation. Example embodiments for adjusting the distance between the workpiece and the separation grid are described in more detail below in the context of FIGS. 2A and 2B and FIGS. 3A, 3B and 3C.

FIGS. 2A and 2B depict example vertical positioning of one or more lift pins to adjust a distance between a separation grid/plasma source and a workpiece in a plasma processing apparatus according to example embodiments of the present disclosure. In FIG. 2A, the lift pin(s) 170 are in a first vertical position so that the workpiece 114 is a first distance d1 from the separation grid 116/plasma chamber 120. The position of the workpiece 114 shown in FIG. 2A can be associated with processing the workpiece using a direct plasma generated by a second plasma source 145. In FIG. 2B, the lift pin(s) 170 are in a second vertical position so that the workpiece 114 is a second distance d2 from the separation grid 116/plasma chamber 120. The second distance d2 can be less than the first distance d1. The position of the workpiece 114 shown in FIG. 2B can be associated with processing the workpiece using a remote plasma source. Other vertical positions are within the scope of the present disclosure. Thus, it will be understood that the workpiece 114 may be adjusted to positions between the first and second distances d1, d2 or other distances depending upon the desired spacing between workpiece 114 and the separation grid 116/plasma chamber 120. The lift pins 170 can be motor-driven, manually adjustable, replaceable, and/or can have any other suitable mechanism operable to adjust the effective length of the lift pins 170.

FIGS. 3A, 3B and 3C depict example vertical positioning of a pedestal to adjust a distance between a separation grid/plasma chamber and a workpiece in a plasma processing apparatus according to example embodiments of the present disclosure. In FIG. 3A, the pedestal 112 is positioned in a first vertical position so that the workpiece 114 is a first distance d1 from the separation grid 116/plasma chamber 120. The position of the pedestal 112 shown in FIG. 3A can be associated with a direct plasma operation. Thus, the position of the pedestal 112 shown in FIG. 3A may be suitable for exposing the workpiece 114 to the direct plasma 115 generated by the second plasma source 145 (e.g., during a plasma etch operation such as reactive ion etching). The first plasma source 135 may be deactivated such that the remote plasma 125 is not generated in the plasma chamber 120 when the pedestal 112 is in the position shown in FIG. 3A. However, separation grid 216 and plasma chamber 220 may act as a gas mixing showerhead for the gas injection into processing chamber 210 when the pedestal 112 is in the position shown in FIG. 3A.

In FIG. 3B, the pedestal 112 is positioned in a second vertical position so that the workpiece is a second distance d2 (e.g., no more than two millimeters (2 mm)) from the separation grid 116/plasma chamber 120. The second distance d2 can be less than the first distance d1. The position of the pedestal 112 shown in FIG. 3B can be associated with a remote plasma operation. Thus, the position of the pedestal 112 shown in FIG. 3B may be suitable for exposing the workpiece 114 to neutral species from the remote plasma 125 generated by the first plasma source 135 in the plasma chamber 120. In certain example embodiments, the second plasma source 145 may also be activated such that the direct plasma 115 is generated in the processing chamber 110 when the pedestal 112 is in the position shown in FIG. 3B. Thus, the workpiece 114 may be exposed to neutral species from the remote plasma 125 and/or the direct plasma 115 when the pedestal 112 is in the position shown in FIG. 3B.

In FIG. 3C, the pedestal 212 is in a third vertical position so that the workpiece is a third distance d3 from the separation grid. The third distance d3 can be greater the first distance d1 and the second distance d2. The position of the pedestal 112 shown in FIG. 3C can be associated with a workpiece loading operation. Other vertical positions are within the scope of the present disclosure. Thus, it will be understood that the workpiece 114 may be adjusted to positions between the second and third distances d2, d3 depending upon the desired spacing between workpiece 114 and the separation grid 116/plasma chamber 120. The movable pedestal 112 can be motor-driven, manually adjustable, and/or can have any other suitable mechanism operable to adjust the vertical position of the pedestal 112.

The pedestal 112 can be adjusted between the first, second and third distances d1, d2, d3 without removing the workpiece 114 from the pedestal 112. Thus, a user of plasma processing apparatus 100 may perform various plasma processing operations on the workpiece 114 by selectively forming the remote plasma 125 in the plasma chamber 120, the direct plasma 115 in the processing chamber 110 and/or by adjusting the vertical position of the pedestal 112 without removing the workpiece 114 from the pedestal 112.

FIG. 4 depicts an example plasma processing apparatus 200 according to example embodiments of the present disclosure. Plasma processing apparatus 200 includes numerous common components with plasma processing apparatus 100 (FIG. 1). For example, plasma processing apparatus 200 includes a processing chamber 210, a substrate holder 212, a separation grid 216, a plasma chamber 220, a dielectric side wall 222, a grounded Faraday shield 228, a gas supply 250 and a top plate 254. Plasma processing apparatus 200 may also include a plasma source 235 with an induction coil 230, a matching network 232 and an RF power generator 234. Thus, plasma processing apparatus 200 may also operate in a similar manner to that described above for plasma processing apparatus 100. In particular, plasma source 235 may be operable to generate a remote plasma in plasma chamber 220. It will be understood that the components of plasma processing apparatus 200 shown in FIG. 4 may also be incorporated into any other suitable plasma processing apparatus in alternative example embodiments. As discussed in greater detail below, plasma processing apparatus 200 includes features for generating a direct plasma in the processing chamber 210.

In plasma processing apparatus 200, an RF bias source 270 is coupled to an electrostatic chuck or bias electrode 275. The bias electrode 275 may be positioned below separation grid 216 within the processing chamber 210. For example, bias electrode 275 may be mounted to the substrate holder 212. The RF bias source 270 is operable to supply RF power to the bias electrode 275. When the bias electrode 275 is energized with RF power from the RF bias source 270, a direct plasma can be induced in the processing chamber 210.

The RF bias source 270 is operable at various frequencies. For example, the RF bias source 270 energize bias electrode 275 with RF power at frequency of about 13.56 MHz. Thus, the RF bias source 270 may energize bias electrode 275 to form a direct capacitively coupled plasma within processing chamber 210. In certain example embodiments, the RF bias source 270 may be operable to energize bias electrode 275 with RF power at frequencies in a range between about 400 KHz and about 60 KHz.

As may be seen from the above, plasma processing apparatus 200 may have a radical source (plasma source 235) positioned above separation grid 216 and may also have a bias electrode 275 positioned below separation grid 216. Thus, induction coil 230 and bias electrode 275 may be positioned opposite each other about separation grid 216. In such a manner, plasma processing apparatus 200 may form a remote plasma within the plasma chamber 220 and may also form a direct plasma within the processing chamber 210.

When the plasma source 235 is deactivated, separation grid 216 and plasma chamber 220 may act as a gas mixing showerhead for the gas injection into processing chamber 210. Thus, when the plasma source 235 is not operating to form the remote plasma, the components of plasma processing apparatus 200 above the processing chamber 210 may assist with forming the direct plasma within the processing chamber 210. When the plasma source 235 operates to form the remote plasma within the plasma chamber 220 and the RF bias source 270 energizes bias electrode 275 to form a direct plasma within processing chamber 210 (i.e., when both the RF power generator 234 and the RF bias source 270 are turned on), the radicals generated from the remote plasma within the plasma chamber 220 can be re-dissociated by the bottom bias on the workpiece 214 provided by bias electrode 275.

Plasma processing apparatus 200 may also include a turbopump assembly 260. The turbopump assembly 260 may have a pressure control valve 262, a pumping selection control valve 264, a turbopump 266 and a foreline pump 268. The pressure control valve 262 can be configured to adjust or regulate pressure within the turbopump assembly 260 and/or the processing chamber 210. Pumping selection control valve 264 can be manually and/or automatically operable to select between one or more pumps, such as turbopump 266 and foreline pump 268, to provide a pumping action to the processing chamber 210. For example, the pumping selection control valve 264 can open a connection to one connected pump while closing one or more connections to one or more other connected pumps.

The turbopump 266 can be a turbomolecular pump with a plurality of stages that each includes a rotating rotor blade and a stationary stator blade. The turbopump 266 can intake gas (e.g. from process chamber 210) at the uppermost stage, and the gas can be pushed to the lowermost stage through various rotor blades and stator blades of the turbopump 266. Turbopump 266 can be independently powered and/or can be powered by foreline pump 268. For example, turbopump 266 can be driven using pressure created by the foreline pump 268 as a backing pump. In particular, the foreline pump 268 can create pressure at a lower end of the turbopump 266, causing the rotor blades in the turbopump 266 to spin, thus causing the pumping action associated with the turbopump 266.

Additionally, the foreline pump 268 can be directly connected to pumping selection control valve 264. For example, the pumping selection control valve 264 can be operable to select the foreline pump 268 to provide high pressure (e.g., about 100 mTorr to about 10 Torr) within the processing chamber 210. The pumping selection control valve 264 can be additionally be operable to select the turbopump 264 to provide low pressure (e.g., about 5 mTorr to about 100 mTorr) within the processing chamber 210.

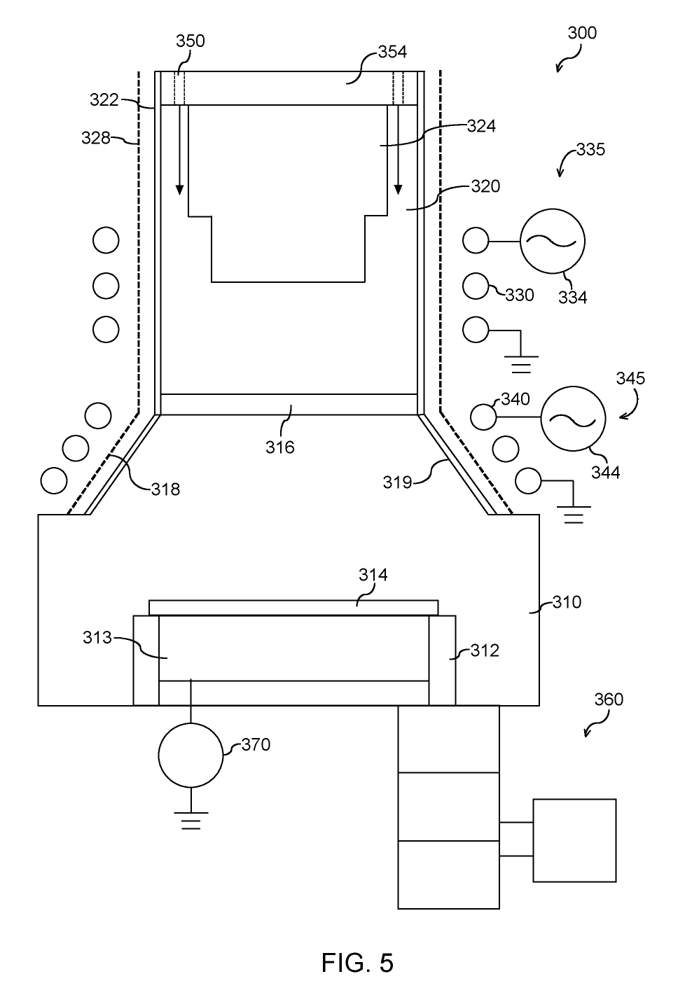

FIG. 5 depicts an example plasma processing apparatus 300 according to example embodiments of the present disclosure. Plasma processing apparatus 300 includes numerous common components with plasma processing apparatus 100 (FIG. 1) and plasma processing apparatus 200 (FIG. 4). For example, plasma processing apparatus 300 includes a processing chamber 310, a substrate holder 312, a separation grid 316, a plasma chamber 320, a dielectric side wall 322, a grounded Faraday shield 328, a gas supply 350, a top plate 354, and a turbopump assembly 360. Plasma processing apparatus 300 may also include a first plasma source 335 with an induction coil 330 and an RF power generator 334. Thus, plasma processing apparatus 300 may operate in a similar manner to that described above for plasma processing apparatus 100 and plasma processing apparatus 200. In particular, plasma source 335 may be operable to generate a remote plasma in plasma chamber 320. It will be understood that the components of plasma processing apparatus 300 shown in FIG. 5 may also be incorporated into any other suitable plasma processing apparatus in alternative example embodiments. As discussed in greater detail below, plasma processing apparatus 300 includes features operable to generate a direct plasma in the processing chamber 310.

In plasma processing apparatus 300, a second plasma source 345 includes an induction coil 340 and an RF power generator 344. As described above in the context of plasma processing apparatus 100, the second plasma source 345 can be operable to generate a direct plasma in the processing chamber 310. For instance, the induction coil 340 of the second plasma source 345 may be disposed adjacent a dielectric window 318. The induction coil 340 can be coupled to RF power generator 344 that is operable to energize the induction coil 340 and thereby generate the direct plasma in the processing chamber 310. The plasma processing apparatus 300 can also include a grounded Faraday shield 319 to reduce capacitive coupling of the induction coil 340 to the direct plasma. The second plasma source 345 of plasma processing apparatus 300 may be constructed in the same or similar manner to that described above for the second plasma source 145 of plasma processing apparatus 100. Thus, plasma processing apparatus 300 may also operate in a similar manner to that described above for plasma processing apparatus 100 to generate a direct plasma in processing chamber 310.

Plasma processing apparatus 300 may further include an RF bias source 370 and an electrostatic chuck or bias electrode 375. As described above in the context of plasma processing apparatus 200, the RF bias source 370 is coupled to the bias electrode 375. When the bias electrode 375 is energized with RF power from the RF bias source 370, a direct plasma can be induced in the processing chamber 310. The RF bias source 370 and bias electrode 375 of plasma processing apparatus 300 may be constructed in the same or similar manner to that described above for the RF bias source 270 and bias electrode 275 of plasma processing apparatus 200. Thus, plasma processing apparatus 300 may also operate in a similar manner to that described above for plasma processing apparatus 200 to generate a direct plasma in processing chamber 310.

As may be seen from the above, plasma processing apparatus 300 may include a second plasma source 345, an RF bias source 370 and a bias electrode 375 to generate a direct plasma in processing chamber 310. The plasma source 345 may be operated simultaneously with RF bias source 370 and bias electrode 375 to generate the direct plasma in processing chamber 310. The plasma source 345 and bias source 370/bias electrode 375 may also be operated independently of each other to generate the direct plasma in processing chamber 310.

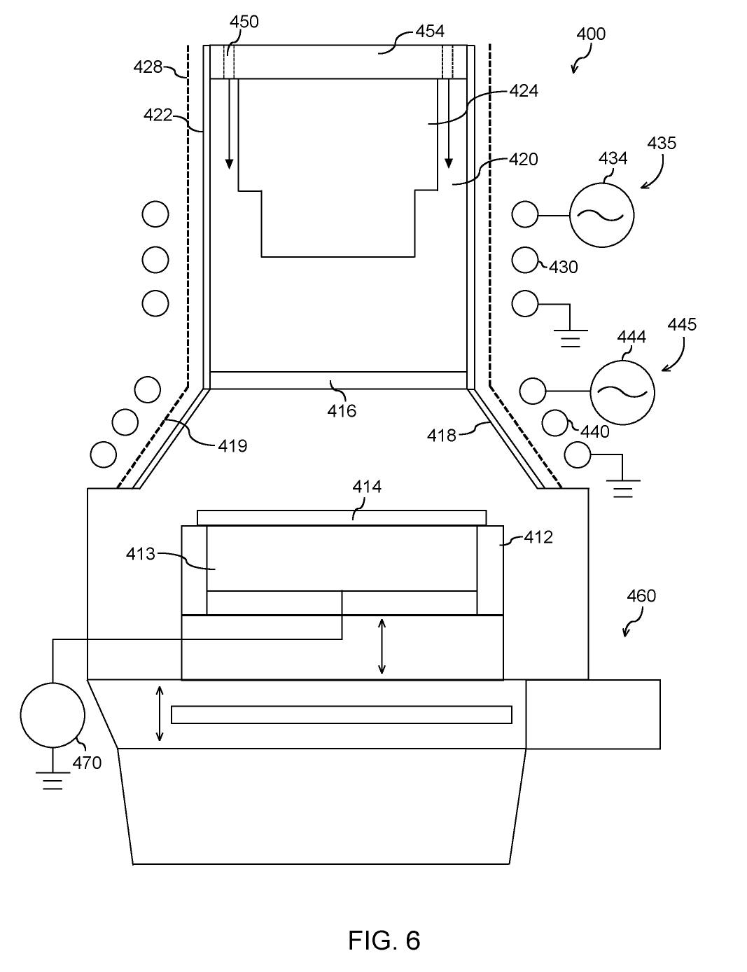

FIG. 6 depicts an example plasma processing apparatus 400 according to example embodiments of the present disclosure. Plasma processing apparatus 400 includes numerous common components with plasma processing apparatus 100 (FIG. 1), plasma processing apparatus 200 (FIG. 4), and plasma processing apparatus 300 (FIG. 5). For example, plasma processing apparatus 400 includes a processing chamber 410, a substrate holder 412, a separation grid 416, a plasma chamber 420, a dielectric side wall 422, a grounded Faraday shield 428, a gas supply 450, a top plate 454, and a turbopump assembly 460. Plasma processing apparatus 400 may also include a first plasma source 435 with an induction coil 430 and an RF power generator 434. Thus, plasma processing apparatus 400 may also operate in a similar manner to that described above for plasma processing apparatus 100 and plasma processing apparatus 200. In particular, plasma source 435 may be operable to generate a remote plasma in plasma chamber 420. It will be understood that the components of plasma processing apparatus 400 shown in FIG. 6 may also be incorporated into any other suitable plasma processing apparatus in alternative example embodiments.

Plasma processing apparatus 400 includes features for generating a direct plasma in the processing chamber 410. For example, plasma processing apparatus 400 includes a second plasma source 445 with an induction coil 440 and an RF power generator 444. As described above in the context of plasma processing apparatus 100, the second plasma source 445 can be operable to generate a direct plasma in the processing chamber 410. For instance, the induction coil 440 of the second plasma source 445 may be disposed adjacent a dielectric window 418. The induction coil 440 can be coupled to RF power generator 444 that is operable to energize the induction coil 440 and thereby generate the direct plasma in the processing chamber 410. The plasma processing apparatus 400 can include a grounded Faraday shield 419 to reduce capacitive coupling of the induction coil 440 to the direct plasma. The second plasma source 445 of plasma processing apparatus 400 may be constructed in the same or similar manner to that described above for the second plasma source 145 of plasma processing apparatus 100. Thus, plasma processing apparatus 400 may also operate in a similar manner to that described above for plasma processing apparatus 100 to generate a direct plasma in processing chamber 410.

Plasma processing apparatus 400 may additionally include an RF bias source 470 and an electrostatic chuck or bias electrode 475. As described above in the context of plasma processing apparatus 200, the RF bias source 470 is coupled to the bias electrode 475. When the bias electrode 475 is energized with RF power from the RF bias source 470, a direct plasma can be induced in the processing chamber 410. The RF bias source 470 and bias electrode 475 of plasma processing apparatus 400 may be constructed in the same or similar manner to that described above for the RF bias source 270 and bias electrode 275 of plasma processing apparatus 200. Thus, plasma processing apparatus 400 may also operate in a similar manner to that described above for plasma processing apparatus 200 to generate a direct plasma in processing chamber 410.

Plasma processing apparatus 400 also includes features for adjusting a distance between a separation grid/plasma chamber and a workpiece in a plasma processing apparatus. In particular, the pedestal 412 is movable along a vertical direction to adjust a distance between the workpiece 414 and the separation grid 416/plasma chamber. Thus, the pedestal 412 may be constructed in the same or similar manner to the pedestal 112 of plasma processing apparatus 100 (FIGS. 3A, 3B, and 3C) in order to allow the pedestal 412 to be positioned at various vertical positions within the processing chamber 410.

In some embodiments, post plasma gas injection (PPGI) can be provided at a separation grid separating the plasma chamber from the processing chamber. Post plasma gas injection can provide for the injection of gas and/or molecules into radicals passing through and/or below a separation grid. FIG. 7 depicts an example separation grid 116 configured for post plasma gas injection according to example embodiments of the present disclosure. More particularly, the separation grid assembly 116 includes a first grid plate 116a and a second grid plate 116b disposed in parallel relationship for ion/UV filtering.

The first grid plate 116a and a second grid plate 116b can be in parallel relationship with one another. The first grid plate 116a can have a first grid pattern having a plurality of holes. The second grid plate 116b can have a second grid pattern having a plurality of holes. The first grid pattern can be the same as or different from the second grid pattern. Charged spec (e.g., ions) can recombine on the walls in their path through the holes of each grid plate 116a, 116b in the separation grid 116. Neutral species (e.g., radicals) can flow relatively freely through the holes in the first grid plate 116a and the second grid plate 116b.

Subsequent to the second grid plate 116b, a gas injection source 117 (e.g., gas port) can be configured to admit a gas into the radicals. The radicals can then pass through a third grid plate 116c for exposure to the workpiece. The gas can be used for a variety of purposes. For instance, in some embodiments, the gas can be a neutral gas or inert gas (e.g., nitrogen, helium, argon). The gas can be used to cool the radicals to control energy of the radicals passing through the separation grid. In some embodiments, a vaporized solvent can be injected into the separation grid 116 via gas injection source 118. In some embodiments, desired molecules (e.g., hydrocarbon molecules) can be injected into the radicals.

The post plasma gas injection illustrated in FIG. 7 is provided for example purposes. Those of ordinary skill in the art will understand that there are a variety of different configurations for implementing one or more gas ports in a separation grid for post plasma gas injection according to example embodiments of the present disclosure. The one or more gas ports can be arranged between any grid plates, can inject gas or molecules in any direction, and can be used to for multiple post plasma gas injection zones at the separation grid for uniformity control. In some embodiments, the gas can be injected at a location beneath the separation grid.

Certain example embodiments can inject a gas or molecules at or below a separation grid in a center zone and a peripheral zone. More zones with gas injection at the separation grid can be provided without deviating from the scope of the present disclosure, such as three zones, four zones, five zones, six zones, etc. The zones can be partitioned in any manner, such as radially, azimuthally, or in any other manner. For instance, in one example, post plasma gas injection at the separation grid can be divided into a center zone and four azimuthal zones (e.g., quadrants) about the periphery of the separation grid.

Example plasma processes that can be implemented using plasma processing apparatus according to example embodiments of the present disclosure. The below plasma processes are provided for example purposes. Other plasma processes can be implemented without deviating from the scope of the present disclosure. In addition, the example plasma processes provided below can be implemented in any suitable plasma processing apparatus.

### Example #1

An anisotropic etching process can be implemented. The process can include providing halogen containing gases to modify surface layers and/or to break bonds on a surface of a workpiece. The process can include energizing ionic species (e.g., with a direct plasma) with energy below workpiece sputtering yield threshold to remove biproducts from the workpiece.

In some embodiments, this example process can include Cl₂ gas or Cl* gas as the halogen containing gas with H₂ or Ar plasma. This example process can be used for Si, SiN, III-V, Cu and refractory metal etching. This example process can be used for TiN or TaN etching.

In some embodiments, this example process can be used, for instance, for Source/Drain recess etching into Si and SiGe workpieces. In some embodiments, this example process can be used for high aspect ratio (HAR) bottom surface clean. In some embodiments, this example process can be used for hardmask patterning.

### Example #2

An anisotropic etching process can be implemented. The process can include implementing ion bombardment, implantation, and/or chemical reaction to modify surface with direct plasma with neutrals and/or energetic ion species. The process can include using halogen, organic, HF/NH₃ gases or reactive species from remote plasma to remove reaction byproducts with heat.

In some embodiments, this example process can include organic/O₂ plasma for Co, Ni, Fe, Cu, Ru, Pd, Pt etching. In some embodiments, this example process can include organic/Ar plasma for III-V, Co, and Cu etching. In some embodiments, the example process can include H₂ plasma/NH₃+NF₃ plasma for selective SiN etching.

In some embodiments, this example process can be used, for instance, for gate nitride spacer etching. In some embodiments, this example process can be used, for instance, for magnetic or noble etching. In some embodiments, this example process can be used for hardmask patterning.

### Example #3

An anisotropic etching process can be implemented. The process can include using plasma based processes to modify or deposit a coating layer on a portion of exposed surfaces of a workpiece. The process can include removing the materials from uncovered surfaces of the workpiece.

In some embodiments, this example process can include CxFy plasma/Ar plasma for selective SiO₂ etching. In some embodiments, this example process can include H₂ plasma/Ar plasma for selective Si etching.

In some embodiments, this example process can be used, for instance, for self-aligned contact etching to prevent spacer. In some embodiments, this example process can be used for high aspect ratio (HAR) bottom surface clean. In some embodiments, this example process can be used for hardmask patterning.

### Example #4

An isotropic etching surface treatment process can be implemented. The process can include forming ammonium halogenated salted on exposed nitride or oxide surfaces of a workpiece. The process can include heating the workpiece to greater than or equal to about 100° C. to remove the salts. In some embodiments, this example process can include SiN, TaN, TiN and SiO2 etching by forming ammonium salts followed by heating to bake.

In some embodiments, this example process can be used for native oxide removal for epi preclean. In some embodiments, this example process can be used I/O oxide recess etching to reveal Si/SiGe structures. In some embodiments, this example process can be used for selective SiN recess etching in 3D NAND ONON stack for floating gate formation. In some embodiments, this example process can be used for selective TiN or TaN etching for WF metal deposition

### Example #5

An isotropic etching surface treatment process can be implemented. The process can include exposing surfaces to halogen based gases or neutrals. The process can include heating the workpiece above sublimation temperature of halogenated species to remove etched materials. In some embodiments, this example process can chlorinate or fluorinate materials such as Si, TiN or TaN followed by heating to bake.

In some embodiments, this example process can be used for SDE lateral recess etching. In some embodiments, this example process can be used for selective Si recess etching in 3D NAND ONON stack for floating gate formation.

### Example #6

An isotropic etching surface treatment process can be implemented. The process can include exposing surfaces to halogen or oxygen based gases or neutrals. The process can include flowing organic or organometallic precursors to remove halogenated species.

In some embodiments, this example process be used for ZrO2, HfO₂, Al₂O₃, AN, SiO₂, ZnO thermal atomic layer etching (ALE) by fluorination followed by organometallic precursor exposure. In some embodiments, this example process can use organic/O₂ plasma for Co, Ni, Fe, Cu, Ru, Pd, Pt etching.

In some embodiments, this example process can be used for magnetic or noble metal etching.

### Example #7

An isotropic etching surface treatment process can be implemented. The process can include exposing surfaces to a halogen based gas or neutral. The process can include exposing halogenated surfaces to a second halogen based gas or neutral to form interhalogen volatile byproducts.

In some embodiments, this example process be used for TiO₂, Ta₂O₅, and WO₃ etching by sequential exposure of WF₆ and BCl₃. In some embodiments, this example process can be used for TiN etching by sequential exposure of F* and Cl₂ (or Cl*)

In some embodiments, this example process can be used for selective TiN or TaN etching for WF metal deposition.

### Further Examples

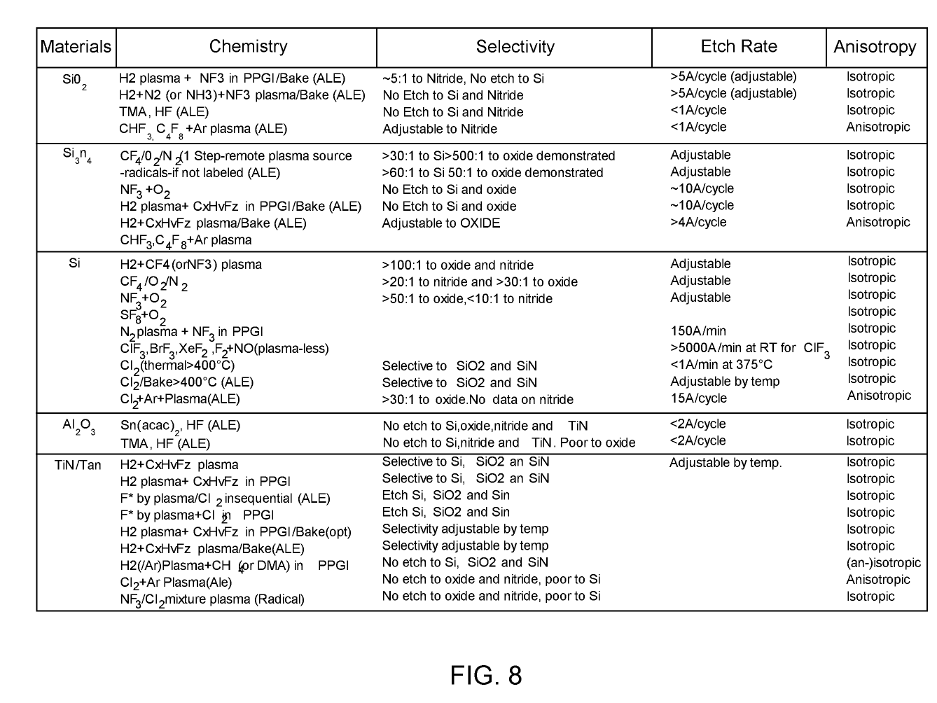

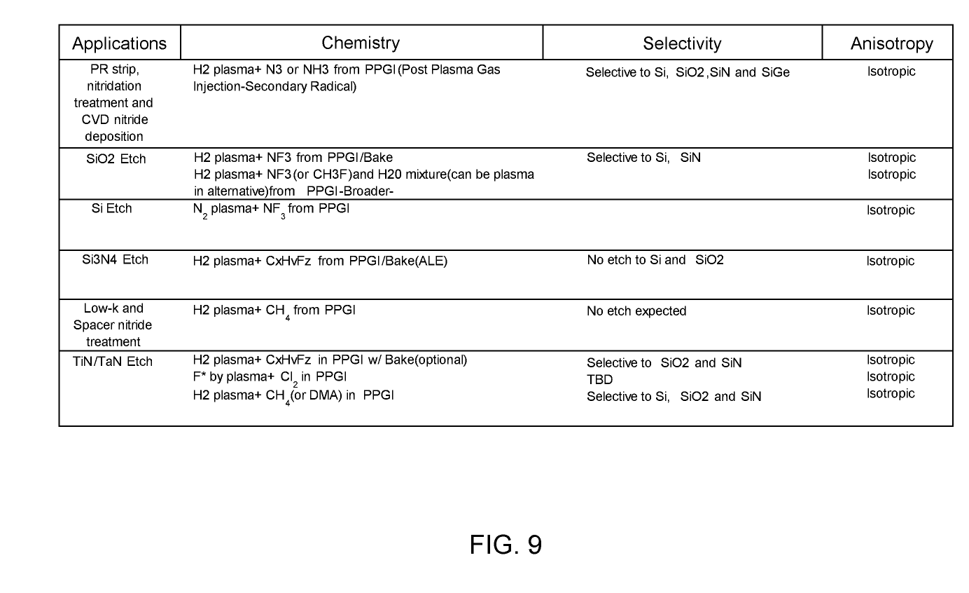

The table in FIG. 8 provides examples of selective removal of commonly used hardmask materials by radical based etching or atomic layer etching (ALE). The table in FIG. 9 provides examples of surface modification/treatment using radicals with post plasma gas injection (PPGI) according to example embodiments of the present disclosure

While the present subject matter has been described in detail with respect to specific example embodiments thereof, it will be appreciated that those skilled in the art, upon attaining an understanding of the foregoing may readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

What is claimed is:

1. A plasma processing apparatus, the plasma processing apparatus comprising:
a processing chamber,
a pedestal disposed in the processing chamber, the pedestal operable to support a workpiece;
a plasma chamber disposed above the processing chamber in a vertical direction, the plasma chamber comprising a dielectric sidewall;
a separation grid separating the processing chamber from the plasma chamber;
a first plasma source proximate the dielectric sidewall of the plasma chamber, the first plasma source operable to generate a remote plasma in the plasma chamber above the separation grid;
a second plasma source, the second plasma source operable to generate a direct plasma in the processing chamber below the separation grid.

2. The plasma processing apparatus of claim 1, wherein the plasma processing apparatus comprises a dielectric window extending from a portion of a processing chamber wall, the dielectric window defining at least a part of the processing chamber.

3. The plasma processing apparatus of claim 2, wherein the second plasma source comprises an induction coil located proximate the second dielectric window.

4. The plasma processing apparatus of claim 1, wherein the separation grid is operable to filter one or more ions generated in the remote plasma, the separation grid operable to pass one or more neutral radicals to the processing chamber.

5. The plasma processing apparatus of claim 1, wherein the plasma processing apparatus comprises a gas source configured to feed a process gas into the plasma chamber.

6. The plasma processing apparatus of claim 5, wherein the separation grid is operable to act as a showerhead for passage of the process gas into the processing chamber.

7. The plasma processing apparatus of claim 1, wherein the pedestal is movable in a vertical direction between at least a first vertical position for performing a first process and a second vertical position for performing a second process, the first vertical position being closer to the separation grid relative to the second vertical position.

8. The plasma processing apparatus of claim 1, wherein the pedestal comprises one or more lift pins movable in a vertical direction between at least a first vertical position for performing a first process and a second vertical position for performing a second process, the first vertical position being closer to the separation grid relative to the second vertical position.

9. The plasma processing apparatus of claim 7, wherein the first process is a dry strip process and the second process is a dry etch process.

10. The plasma processing apparatus of claim 1, wherein the first plasma source comprises an induction coil disposed about the dielectric sidewall.

11. The plasma processing apparatus of claim 1, wherein the second plasma source comprises an RF bias electrode associated with the pedestal, the RF bias electrode operable to generate the direct plasma in the processing chamber when the RF bias electrode is energized with RF energy from an RF bias source.

12. A plasma processing apparatus, the plasma processing apparatus comprising:
a processing chamber,
a pedestal disposed in the processing chamber, the pedestal operable to support a workpiece;
a plasma chamber disposed above the processing chamber in a vertical direction, the plasma chamber comprising a dielectric sidewall, the dielectric sidewall having a cylindrical shape;
a separation grid separating the processing chamber from the plasma chamber;
a dielectric window forming a portion of a ceiling of the processing chamber, the dielectric window flaring outward in a horizontal direction from the plasma chamber;
a first plasma source proximate the dielectric sidewall, the first plasma source operable to generate a remote plasma in the plasma chamber;
a second plasma source proximate the dielectric window, the second plasma source operable to generate a direct plasma in the processing chamber.

13. The plasma processing apparatus of claim 12, wherein the first plasma source comprises an induction coil disposed about the dielectric sidewall.

14. The plasma processing apparatus of claim 12, wherein the second plasma source comprises an induction coil disposed proximate the dielectric window.

15. The plasma processing apparatus of claim 12, further comprising an RF bias electrode associated with the pedestal, the RF bias electrode operable to generate a direct plasma in the processing chamber when the RF bias electrode is energized with RF energy from an RF bias source.

16. The plasma processing apparatus of claim 12, wherein the pedestal is movable in a vertical direction between at least a first vertical position for performing a first process and a second vertical position for performing a second process, the first vertical position being closer to the separation grid relative to the second vertical position.

17. The plasma processing apparatus of claim 12, wherein the pedestal comprises one or more lift pins movable in a vertical direction between at least a first vertical position for performing a first process and a second vertical position for performing a second process, the first vertical position being closer to the separation grid relative to the second vertical position.

18. A plasma processing apparatus, comprising:
a processing chamber,
a pedestal disposed in the processing chamber, the pedestal operable to support a workpiece;
a plasma chamber disposed above the processing chamber in a vertical direction, the plasma chamber comprising a dielectric sidewall, the dielectric sidewall having a cylindrical shape;
a separation grid separating the processing chamber from the plasma chamber;
a first plasma source proximate the dielectric sidewall, the first plasma source operable to generate a remote plasma in the plasma chamber;
a second plasma source, the second plasma source operable to generate a direct plasma in the processing chamber, the second plasma source comprising an RF bias electrode associated with the pedestal, the RF bias electrode operable to generate the direct plasma in the processing chamber when the RF bias electrode is energized with RF energy from an RF bias source.

19. The plasma processing apparatus of claim 18, wherein the pedestal is movable in a vertical direction between at least a first vertical position for performing a first process and a second vertical position for performing a second process, the first vertical position being closer to the separation grid relative to the second vertical position.

20. The plasma processing apparatus of claim 19, wherein the pedestal comprises one or more lift pins movable in a vertical direction between at least a first vertical position for performing a first process and a second vertical position for performing a second process, the first vertical position being closer to the separation grid relative to the second vertical position.
